(19) United States
(12) Patent Application Publication
(10) Pub. No.: US 2026/0147057 A1
(43) Pub. Date: May 28, 2026

(54) STORAGE BATTERY MANAGEMENT DEVICE AND METHOD FOR MANAGING STORAGE BATTERY

(71) Applicant: MUSASHI SEIMITSU INDUSTRY CO., LTD., TOYOHASHI-SHI, AICHI (JP)

(72) Inventor: Kenji HAMADA, TOYOHASHI-SHI, AICHI (JP)

(21) Appl. No.: 18/868,510

(22) PCT Filed: Jun. 28, 2022
(86) PCT No.: PCT/JP2022/025765

§ 371 Date: Nov. 22, 2024

(51) Int. Cl. G01R 31/392; G01R 31/367; G01R 31/3842

(52) U.S. Cl. CPC G01R 31/392; G01R 31/367; G01R 31/3842

(57) ABSTRACT

To estimate the SOC of the storage battery with high accuracy, the storage battery management device manages a storage battery having SOC-OCV characteristics including a plateau region, and multiple change regions in which an OCV change rate is relatively high. The storage battery management device includes: an OCV acquisition unit that acquires the OCV of the storage battery; a first SOC estimation unit that estimates a first SOC based on the OCV of the storage battery and the SOC-OCV characteristics when the OCV of the storage battery is within a first change region; and a second SOC estimation unit that estimates a second SOC based on the OCV, the SOC-10 OCV characteristics, and a correlation value that correlates with the degradation state of the storage battery when the OCV of the storage battery is within the other change regions other than the first change region.

### TECHNICAL FIELD

The technology disclosed herein relates to a storage battery management device and a method for managing a storage battery.

### BACKGROUND ART

The open circuit voltage (OCV) method is known as a method for estimating the state of charge (SOC) of storage batteries (see, e.g., Patent Literature 1). The OCV method acquires the OCV of a storage battery to estimate the SOC based on the correspondence between the acquired OCV and the SOC-OCV characteristic curve of the storage battery. In the OCV method, the period for estimating the SOC can be limited to the period when the OCV of the storage battery is available, and the SOC of the storage battery may not be estimated accurately for storage batteries with SOC-OCV characteristics that include a region where the absolute value of a change amount of the OCV relative to the change amount of the SOC is relatively small (e.g., plateau region). The current integration method is another well-known method for estimating the SOC of storage batteries. In the current integration method, the change amount of the capacity of the storage battery from the initial state is calculated by integrating the measurement results of the current flowing through the storage battery, and the SOC is estimated based on the initial capacity, the calculated capacity change, and the full charge capacity (FCC). Unlike the OCV method, the current integration method can estimate the SOC without being affected by the limitation of the period during which the OCV is available or by the plateau region; however, the SOC may not be accurately estimated due to measurement errors in the current measurement unit that measures the current flowing through the storage battery. With regard to this, a method that combines the current integration method and the OCV method is known (see, e.g., Patent Literature 2). This method resets the initial capacity to the SOC estimated by the OCV method at each point in time when the OCV can be measured, thereby eliminating the integration error caused by the measurement error of the current measurement unit.

### CITATION LIST

### Patent Literature

Patent Literature 1: JP 2021-081244 A
Patent Literature 2: JP 2020-060581 A

### SUMMARY OF INVENTION

### Technical Problem

When the SOC of a storage battery is estimated by using SOC-OCV characteristics prepared in advance, the characteristics may include an error between the assumed state and the actual state of the storage battery (hereinafter referred to as “storage battery state error”). Factors that may cause the storage battery state error include individual differences in the battery at the time of shipment and aging. Therefore, when the SOC of a storage battery is estimated by using the SOC-OCV characteristics, the SOC cannot be estimated accurately.

Disclosed herein is a technology that can solve the problems mentioned above.

### Solution to Problem

The technology disclosed herein can be implemented in the following aspects.

(1) A storage battery management device disclosed herein is a device for managing a storage battery having SOC-OCV characteristics including a plateau region in which an OCV change rate, which is the absolute value of the change amount of the OCV relative to the change amount of the SOC, is relatively low, and multiple change regions in which the OCV change rate is relatively high, the storage battery management device including: an OCV acquisition unit that acquires the OCV of the storage battery; a first SOC estimation unit that estimates a first SOC based on the OCV of the storage battery and the SOC-OCV characteristics when the OCV of the storage battery acquired by the OCV acquisition unit is within a first change region which is the change region including 100% SOC; and a second SOC estimation unit that estimates a second SOC based on the OCV of the storage battery, the SOC-OCV characteristics, and a correlation value that correlates with the degradation state of the storage battery when the OCV of the storage battery is within the other change regions other than the first change region.

When the OCV of the storage battery is within the first change region including 100% SOC, the SOC estimated based on the SOC-OCV characteristics is highly accurate because the effect of the storage battery state error is small. When the OCV of the storage battery is within the other change regions, the SOC estimated based on the SOC-OCV characteristics is less accurate because the effect of the storage battery state error is large. Therefore, in this storage battery management device, when the OCV of the storage battery is within the first change region, the first SOC is estimated based on the OCV of the storage battery and the SOC-OCV characteristics. On the other hand, when the OCV of the storage battery is within the other change regions, the second SOC is estimated based on the OCV of the storage battery, the SOC-OCV characteristics, and the correlation value that correlates with the degradation state of the storage battery. Therefore, this storage battery management device can accurately estimate the SOC of the storage battery.

(2) The above storage battery management device may be configured to further include: a current measurement unit that measures the current flowing through the storage battery; a coulomb counting processing unit that calculates the capacity of the storage battery by integrating the current measured by the current measurement unit; a first reference SOC setting unit that sets the SOC estimated by the first SOC estimation unit as the SOC at the first reference time when the OCV of the storage battery is within the first change region; and a correlation value correction unit that corrects the correlation value on the condition that the OCV of the storage battery moves from the first change region to a second change region where the OCV is equal to or smaller than a predetermined value among the other change regions, wherein the correlation value correction unit may be configured to correct the correlation value based on the SOC estimated by the second SOC estimation unit based on the OCV after moving to the second change region, the SOC at the first reference time, and the change amount of the capacity of the storage battery calculated by the coulomb counting processing unit during the time period in which the OCV of the storage battery moves from the first change region to the second change region. This storage battery management device corrects the correlation value according to changes in the state of the storage battery due to deterioration or the like. As a result, this storage battery management device can accurately estimate the SOC of the storage battery while suppressing the effects of changes in the state of the storage battery.

(3) The above storage battery management device may be configured to further include: a current measurement unit that measures the current flowing through the storage battery; a coulomb counting processing unit that calculates the capacity of the storage battery by integrating the current measured by the current measurement unit; a first reference SOC setting unit that sets the SOC estimated by the second SOC estimation unit as the SOC at the first reference time when the OCV of the storage battery is within a second change region where the OCV is equal to or smaller than a predetermined value among the other change regions; and a correlation value correction unit that corrects the correlation value on the condition that the OCV of the storage battery moves from the second change region to the first change region, wherein the correlation value correction unit may be configure to correct the correlation value based on the SOC estimated by the first SOC estimation unit based on the OCV after moving to the first change region, the SOC at the first reference time, and the change amount of the capacity of the storage battery calculated by the coulomb counting processing unit during the time period in which the OCV of the storage battery moves from the second change region to the first change region. This storage battery management device corrects the correlation value according to changes in the state of the storage battery due to deterioration or the like. As a result, this storage battery management device can accurately estimate the SOC of the storage battery while suppressing the effects of changes in the state of the storage battery.

(4) The above storage battery management device may be configured to further include: a second reference SOC setting unit that sets the SOC estimated by the first SOC estimation unit or the second SOC estimation unit as the SOC at the second reference time; an integrated SOC estimation unit that estimates the integrated SOC of the storage battery based on the SOC at the second reference time, the change amount of the capacity of the storage battery from the second reference time calculated by the coulomb counting processing unit, and the FCC of the storage battery; and an FCC correction unit that corrects the FCC based on the corrected correlation value corrected by the correlation value correction unit. This storage battery management device can accurately estimate the SOC based on the current integration method because the FCC is corrected based on the correlation value that correlates with the degradation state of the storage battery.

(5) A method disclosed herein is a method for managing a storage battery having SOC-OCV characteristics including a plateau region in which an OCV change rate, which is the absolute value of the change amount of the OCV relative to the change amount of the SOC, is relatively low, and multiple change regions in which the OCV change rate is relatively high, the method including: a step of acquiring the OCV of the storage battery; and a step of estimating the first SOC based on the OCV of the storage battery and the SOC-OCV characteristics when the acquired OCV of the storage battery is within a first change region which is the change region including 100% SOC; and a step of estimating a second SOC based on the OCV of the storage battery, the SOC-OCV characteristics, and a correlation value that correlates with the degradation state of the storage battery when the OCV of the storage battery is within the other change regions other than the first change region. This method for managing a storage battery can accurately estimate the SOC of the storage battery.

The technology disclosed herein can be implemented in various aspects, such as a storage battery management device, a battery device equipped with a storage battery management device and a storage battery, a method for managing those devices, a computer program that implements those methods, and a non-temporary recording medium that records that computer program, among others.

### BRIEF DESCRIPTION OF DRAWINGS

FIG. 1 is an explanatory view schematically illustrating a configuration of a battery device 100 in an embodiment.

FIG. 2 is an explanatory view schematically illustrating SOC-OCV characteristics of a storage battery 12.

FIG. 3 is an explanatory view illustrating an example of an SOC-OCV table T1.

FIG. 4 is an explanatory view illustrating an example of region classification-OCV table T2.

FIG. 5 is a flowchart showing an OCV acquisition process.

FIG. 6 is a flowchart showing an SOC reset process.

### DESCRIPTION OF EMBODIMENTS

### A. Embodiment

### A-1. Configuration of Battery Device 100:

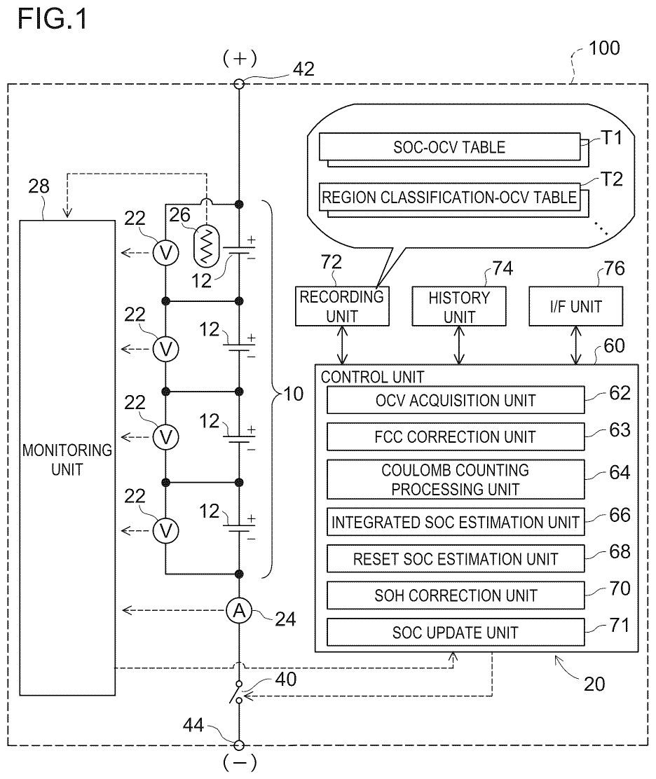

FIG. 1 is an explanatory view schematically illustrating a configuration of a battery device 100 in an embodiment. The battery device 100 includes a battery assembly 10 and a storage battery management device 20.

The battery assembly 10 has a configuration in which a plurality of the storage batteries 12 are connected in series. In this embodiment, the battery assembly 10 consists of four storage batteries 12. The battery assembly 10 is connected to a load and an external power source, not shown, via a positive terminal 42 and a negative terminal 44.

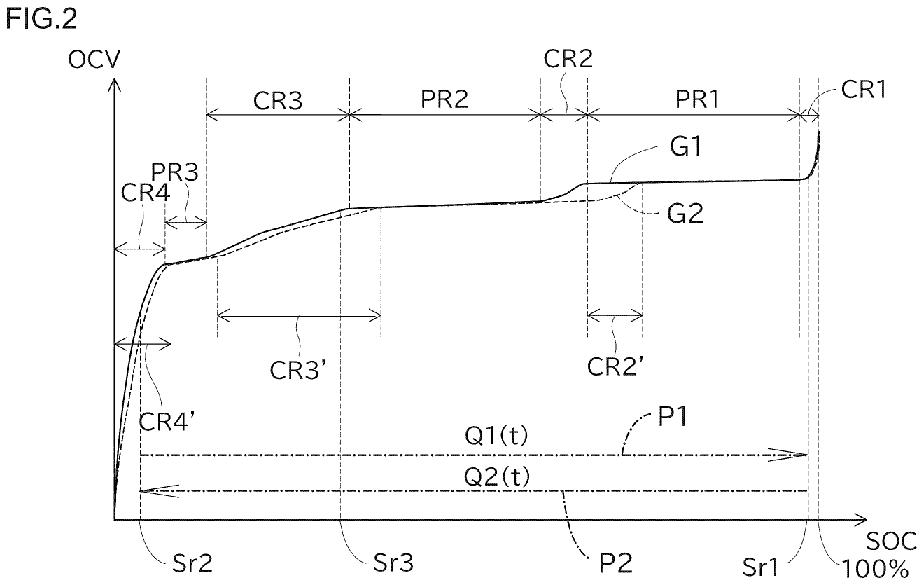

Each of the storage batteries 12 constituting the battery assembly 10 is a storage battery having state of charge-open circuit voltage (SOC-OCV) characteristics that include a plateau region PR. FIG. 2 is an explanatory view schematically illustrating SOC-OCV characteristics of the storage battery 12. Examples of the storage battery 12 may include iron phosphate lithium ion batteries and titanic acid lithium ion batteries.

The SOC-OCV characteristics of the storage battery 12 include a plateau region PR and a change region CR. The plateau region PR is a region where the curve representing the SOC-OCV characteristics is almost flat, or more specifically, where the OCV change rate (absolute value of the OCV change amount relative to the SOC change amount) is equal to or smaller than a predetermined value (e.g., 2 mV/%). The change region CR is the region where the OCV change rate exceeds the predetermined value (non-plateau region). In the example shown in FIG. 2, three plateau regions PR (first plateau region PR1, second plateau region PR2, and third plateau region PR3) and four change regions CR appear alternately in the SOC-OCV characteristics of the storage battery 12. Hereafter, the change region including 100% SOC is also referred to as “uppermost change region CR1”, the change region including 0% SOC as “lowermost change region CR4”, and the other change regions as “intermediate change regions CR2 and CR3”.

Graph G1 in FIG. 2 shows the SOC-OCV characteristics when the storage battery 12 is new, and graph G2 shows the SOC-OCV characteristics when the storage battery 12 has deteriorated over time. As can be seen from these graphs G1 and G2, as the storage battery 12 deteriorates, in the SOC-OCV characteristics, the uppermost change region CR1 almost remains unchanged, but the other change regions CR2 to CR4 shift to the high SOC side (see change regions CR2′ to CR4′). The uppermost change region CR1 is an example of the first change region in the claims, and the lowermost change region CR4 is an example of the second change region in the claims.

The storage battery management device 20 is a device for managing a battery device 100 including a battery assembly 10. The storage battery management device 20 includes a voltmeter 22, an ammeter 24, a thermometer 26, a monitoring unit 28, a line switch 40, a control unit 60, a recording unit 72, a history unit 74, and an interface (I/F) unit 76.

One voltmeter 22 is provided for each storage battery 12. Each voltmeter 22 is connected in parallel to each storage battery 12, measures the voltage of each storage battery 12, and outputs a signal indicating the measured voltage to the monitoring unit 28. The ammeter 24 is connected in series to the battery assembly 10. The ammeter 24 measures the current flowing through the battery assembly 10 and outputs a signal indicating the measured current to the monitoring unit 28. The thermometer 26 is located near the battery assembly 10. The thermometer 26 measures the temperature of the battery assembly 10 (each storage battery 12) and outputs a signal indicating the measured temperature to the monitoring unit 28. Based on the signals received from the voltmeter 22, the ammeter 24, and the thermometer 26, the monitoring unit 28 outputs signals indicating the voltage of each storage battery 12, the current flowing through the battery assembly 10, and the temperature of the battery assembly 10 (each storage battery 12) to the control unit 60. The combination of the ammeter 24 and the monitoring unit 28 is an example of the current measurement unit.

The line switch 40 is provided between the battery assembly 10 and the negative terminal 44. The line switch 40 is controlled on and off by the control unit 60 to open and close the connection between the battery assembly 10 and the load/external power source.

The control unit 60 is configured by using, e.g., a CPU, a multi-core CPU, or a programmable device (such as a field programmable gate array (FPGA), a programmable logic device (PLD)) to control the operation of the storage battery management device 20. The control unit 60 has functions as an OCV acquisition unit 62, a coulomb counting processing unit 64, an integrated SOC estimation unit 66, a reset SOC estimation unit 68, an SOH correction unit 70, and an SOC update unit 71. The functions of each of these units will be described in conjunction with the description of the SOC estimation process below.

The recording unit 72 is composed of, e.g., ROM, RAM, or a hard disk drive (HDD), and is used to store various programs and data, or as a work area or data storage area when executing various processes. For example, the recording unit 72 stores a computer program for executing the SOC estimation process described below. The computer program is provided, e.g., in the form of a computer-readable recording medium (not shown) such as a CD-ROM, DVD-ROM, and USB memory, and is stored in the recording unit 72 by being installed in the battery device 100.

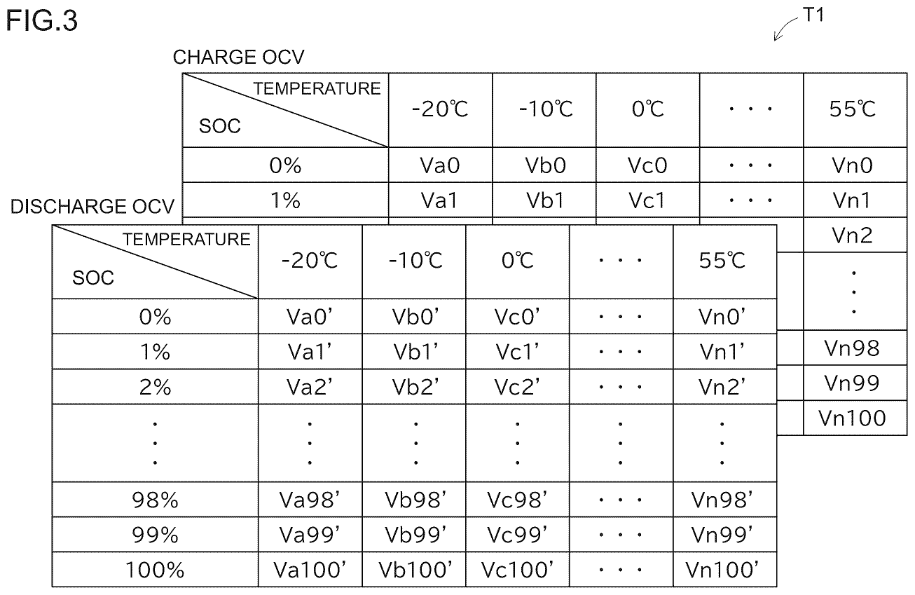

The recording unit 72 also stores an SOC-OCV table T1 and a region classification-OCV table T2. The SOC-OCV table T1 is a table used for SOC estimation based on the OCV method for each of the storage batteries 12. FIG. 3 is an explanatory view illustrating an example of the SOC-OCV table T1. The SOC-OCV table T1 is a table that associates the OCV, the battery temperature, and the SOC. The relationship specified in the SOC-OCV table T1 is experimentally determined in advance. As shown in FIG. 3, the SOC-OCV characteristics fluctuate with changes in battery temperature. By referring to the SOC-OCV table T1, the SOC of each storage battery 12 can be estimated based on the OCV of each storage battery 12 and the battery temperature. In FIG. 3, OCV is indicated as Vn0, Vn1, . . . Vn99, Vn100, but the actual SOC-OCV table T1 defines the numerical value of the OCV. In addition, FIG. 3 shows the SOC-OCV table for discharge, which is used when discharging the storage battery 12, and the SOC-OCV table for charge, which is used when charging the storage battery 12.

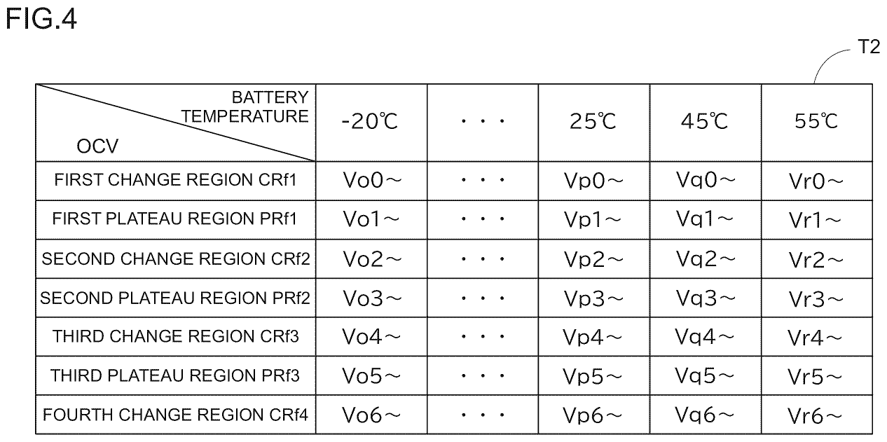

The region classification-OCV table T2 (FIG. 1) recorded in the recording unit 72 is used to determine in which region (plateau region PR, change region CR) the measured OCV is located (belongs to which region) in the SOC-OCV characteristics. FIG. 4 is an explanatory view illustrating an example of region classification-OCV table T2. In this embodiment, the region classification-OCV table T2 defines the relationship among the OCV, each region classification in the SOC-OCV characteristics, and the battery temperature. As mentioned above, since the SOC-OCV characteristics fluctuate in accordance with changes in battery temperature, each region classification in the SOC-OCV characteristics fluctuates in accordance with the fluctuation of the SOC-OCV characteristics. In FIG. 4, the OCV is indicated as Vo0, Vo1, . . . , but the actual region classification-OCV table T2 defines the numerical value of the OCV.

The history unit 74 is composed of, e.g., ROM, RAM, and a hard disk drive (HDD), and records various histories related to the battery device 100. Such history includes, e.g., histories of the OCV of the storage battery 12 and the SOC process described below. The interface unit 76 communicates with other devices by wired or wireless means. For example, the history recorded in the history unit 74 is updated by communication with other devices via the interface unit 76.

### A-2. Soc Estimation Process:

The SOC estimation process performed by the storage battery management device 20 in the battery device 100 of this embodiment is described. In this embodiment, the SOC estimation process estimates the SOC individually for each of the storage batteries 12 that constitute the battery assembly 10. The following description focuses on one storage battery 12. The SOC estimation process is started, e.g., automatically when the storage battery management device 20 is activated or in response to instructions from the administrator.

### A-2-1. Estimation Process of Integrated Soc (T) Based on Current Integration Method:

The battery device 100 of this embodiment performs a process to estimate the SOC based on the current integration method (hereinafter referred to as “integrated SOC(t)”). Specifically, the coulomb counting processing unit 64 (FIG. 1) of the storage battery management device 20 calculates the capacity of each storage battery 12 by integrating the currents measured by the ammeter 24 and the monitoring unit 28. Next, the integrated SOC estimation unit 66 of the storage battery management device 20 estimates the integrated SOC(t) of the storage batteries based on the SOC (0) at the reference time (hereinafter referred to as “integrated reference time SOC (0)”), the change amount of the capacity Q(t) (charge transfer) of the storage batteries 12 from the reference time calculated by the coulomb counting processing unit 64, and the FCC of the storage batteries 12. The integrated SOC(t) can be represented by the following Equation (1).

$$integrated SOC ( t ) = integrated reference time SOC ( 0 ) + [ Q ( t ) / FCC ] \qquad ( 1 )$$

At the start of the SOC estimation process, the reference time is the time at which the battery device 100 is shipped, and thereafter, the reference time is the time at which the reference SOC update process is performed in the SOC reset process described below. The estimation process of the integrated SOC(t) is continuously executed during the SOC estimation process. The integrated SOC estimation unit 66 is an example of the third estimation unit in the claims, and the integrated reference time SOC(0) is an example of the SOC at the second reference time in the claims.

### A-2-2. OCV Acquisition Process:

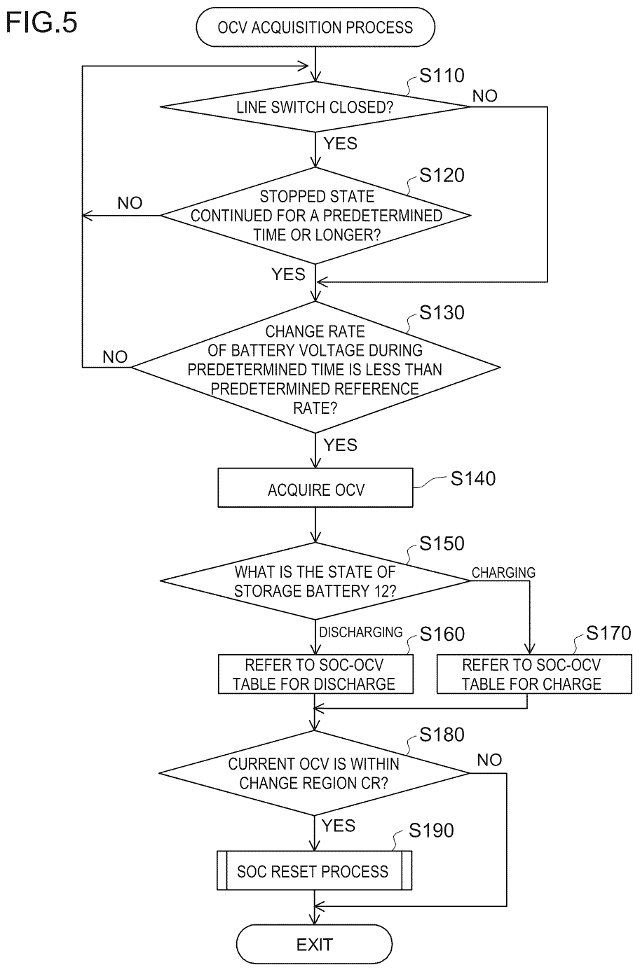

FIG. 5 is a flowchart showing an OCV acquisition process performed in the battery device 100. When the current of charge or discharge to/from the storage battery 12 falls below a predetermined threshold value or when the line switch 40 shifts from the closed state to the open state, the control unit 60 determines that the storage battery 12 is in a stopped state, and the OCV acquisition unit 62 (FIG. 1) of the storage battery management device 20 executes the OCV acquisition process (FIG. 5) for the storage battery 12. Specifically, the OCV acquisition unit 62 determines whether or not the OCV acquisition timing has arrived, and if it determines that the OCV acquisition timing has arrived, the OCV acquisition unit 62 performs the OCV acquisition process (S110 to S140). In this system, the OCV acquisition timing for the storage battery 12 is the timing at which it is detected that the polarization of the storage battery 12 has resolved to stabilize the battery voltage to the extent that the OCV of the storage battery 12 can be acquired.

As shown in FIG. 5, the OCV acquisition unit 62 again determines whether the line switch 40 is in the closed state (S110). The line switch 40 being in the closed state means that the storage battery 12 (battery assembly 10) is electrically connected to a load, and the line switch 40 being in the open state means that the storage battery 12 is in the no-load state, not electrically connected to a load (not shown).

When the OCV acquisition unit 62 determines that the line switch 40 is in the closed state (S110: YES), the OCV acquisition unit 62 determines whether the stopped state in which no current flows to the storage battery 12 has continued for a predetermined time or longer (S120). The control unit 60 always determines the presence or absence of current flowing through the storage battery 12 based on the signals input from the monitoring unit 28 and keeps the results of the determination as a history associated with the elapsed time, and the OCV acquisition unit 62 can determine whether the stopped state of the storage battery 12 has continued for a predetermined time or longer based on this history. The OCV acquisition unit 62 determines that the current state of the storage battery 12 is in the stopped state if the current flowing through the storage battery 12 is a reference current value (a value at which the current can be regarded as approximately zero) or less. The measurement of the current in the storage battery 12 is continuously executed during the SOC estimation process.

If the OCV acquisition unit 62 determines that the stopped state of the storage battery 12 has not continued for a predetermined time or longer (S120: NO), the process returns to S110. In contrast, if the OCV acquisition unit 62 determines that the stopped state of the storage battery 12 has continued for a predetermined time or longer (S120: YES), the OCV acquisition unit 62 determines, based on the signal input from the monitoring unit 28, whether the change rate of the battery voltage of the storage battery 12 during the predetermined time is less than a predetermined reference rate (a value at which the battery voltage of the storage battery 12 is considered to be approximately stable) (S130). The measurement of the voltage of the storage battery 12 is continuously executed during the SOC estimation process. When it is determined that the line switch 40 is in the open state (S110: NO), the OCV acquisition unit 62 proceeds to S130 without performing the process in S120.

If the OCV acquisition unit 62 determines that the change rate of the battery voltage of the storage battery 12 during the predetermined time is the reference rate or higher (S130: NO), the process returns to S110. In contrast, if the OCV acquisition unit 62 determines that the change rate of the battery voltage of the storage battery 12 during the predetermined time is less than the reference rate (S130: YES), the OCV acquisition unit 62 records the measured battery voltage of the storage battery 12 in the history unit 74 as the OCV of the storage battery 12 (S140).

Next, the control unit 60 determines whether the OCV of the storage battery 12 acquired at the current OCV acquisition timing (hereinafter referred to as “the current OCV”) is within the change region CR.

Specifically, the control unit 60 determines the current state (charge state or discharge state) of the storage battery 12 immediately before the OCV acquisition timing (S150). For example, the signal output from the ammeter 24 corresponds to the presence/absence and direction of the current flowing through the storage battery 12 (a signal corresponding to the high and low voltage at both ends of the detection resistor (not shown) provided in the ammeter 24). The control unit 60 determines the current state (charge or discharge state) of the storage battery 12 based on the level of the signal output from the ammeter 24 and the level reversal of that signal.

When it is determined that the storage battery 12 is in the state of discharge (S150: discharging), the control unit 60 refers to the SOC-OCV table for discharge (S160) to determine whether the current OCV is within the change region CR in the SOC-OCV characteristics for discharge (S180). On the other hand, when it is determined that the storage battery 12 is in the state of charge (S150: charging), the control unit 60 refers to the SOC-OCV table for charge (S170) to determine whether the current OCV is within the change region CR in the SOC-OCV characteristics for charge (S180).

When it is determined that the current OCV is within the change region CR in the SOC-OCV characteristics for discharge or the SOC-OCV characteristics for charge (S180: YES), the control unit 60 proceeds to the SOC reset process (S190). On the other hand, when it is determined that the current OCV is not within the change region CR (S180: NO), the control unit 60 returns to S110 without performing the SOC reset process.

### A-2-3. Soc Reset Process:

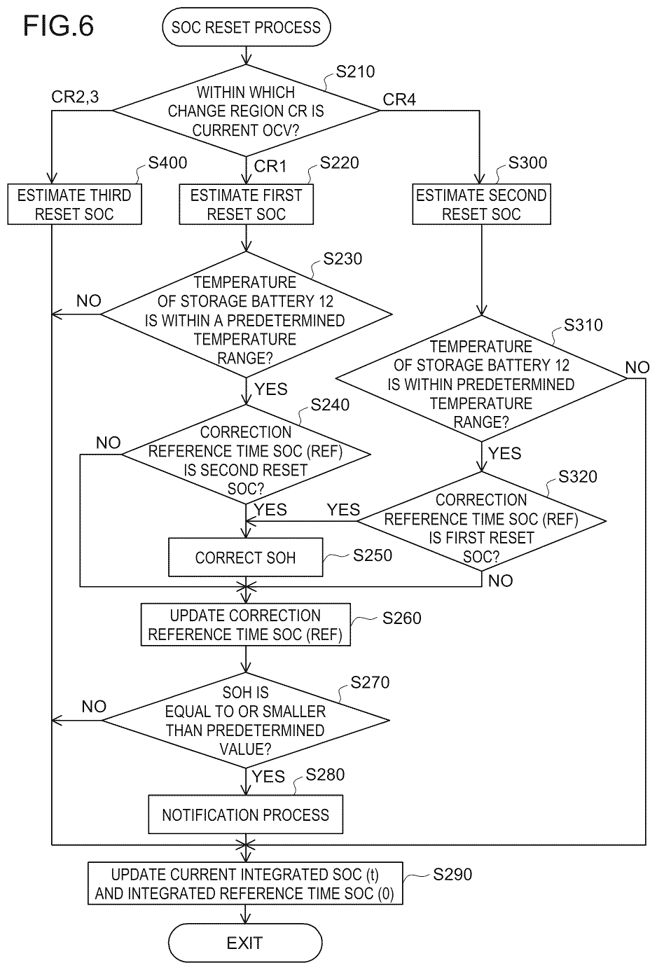

FIG. 6 is a flowchart showing the SOC reset process executed in the battery device 100. The SOC reset process is a process to estimate the reset SOC (first reset SOC, second reset SOC, and third reset SOC) based on the OCV method and reset (update) the integrated SOC (t) estimated by the integrated SOC estimation unit 66 to the reset SOC.

In the SOC reset process, the reset SOC used in the SOC reset process differs depending on which change region CR (uppermost change region CR1, intermediate change regions CR2 and CR3, and lowermost change region CR4) the current OCV is within in the SOC-OCV characteristics.

A-2-3-1. When Current OCV is within the Uppermost Change Region CR1:

When it is determined that the current OCV is within the uppermost change region CR1 (S210: CR1), the reset SOC estimation unit 68 estimates the first reset SOC based on the current OCV of the storage battery 12 and the SOC-OCV characteristics (S220). In this case, the reset SOC estimation unit 68 functions as the first SOC estimation unit in the claims. In the example in FIG. 2, when the current OCV is within the uppermost change region CR1 in the SOC-OCV characteristics, the reset SOC estimation unit 68 refers to the SOC-OCV table T1 to estimate the SOC corresponding to the current OCV (“Sr1” in FIG. 2) as the first reset SOC. In this estimation process of the first reset SOC, the SOH described below is not used.

Next, the control unit 60 determines whether the temperature of each storage battery 12 is within a predetermined temperature range based on the signal indicating the temperature from the monitoring unit 28 (S230). The predetermined temperature range is, e.g., a temperature range within which the correlation between the degradation state and the state of health (SOH) of the storage battery 12 is normally established (e.g., 20° C. or higher and 45° C. or lower). If the temperature of the storage battery 12 is determined to be within the predetermined temperature range (S230: YES), the SOH can be appropriately corrected by using the reset SOC estimated by the reset SOC estimation unit 68.

Therefore, the SOH correction unit 70 corrects the SOH on the condition that the OCV of the storage battery 12 has moved from the lowermost change region CR4 to the uppermost change region CR1. The SOH is a value (parameter) that correlates with the degradation state of the storage battery 12.

Specifically, the control unit 60 determines whether the SOC set in the previous SOH correction process (hereinafter referred to as “correction reference time SOC (REF)”) is the SOC estimated by the reset SOC estimation unit 68 when the OCV is within the lowermost change region CR4 (hereinafter referred to as “second reset SOC” (Sr2 in FIG. 2) (S240). The fact that it is determined that the correction reference time SOC (REF) is the second reset SOC (S240: YES) means that the OCV of the storage battery 12 has moved from the lowermost change region CR4 to the uppermost change region CR1.

Therefore, the SOH correction unit 70 corrects the SOH based on the value Sr1 of the first reset SOC, the value Sr2 of the correction reference time SOC (REF) (second reset SOC), and the change amount Q1(t) of capacity of the storage battery 12 calculated by the coulomb counting processing unit 64 during the period in which the OCV of the storage battery 12 moved from the lowermost change region CR4 to the uppermost change region CR1 (S250, see arrow P1 in FIG. 2). For example, the corrected SOH can be calculated by the following equations (2) and (3).

$$current FCC = Q 1 ( t ) / [ ( Sr 1 ) - ( S r 2 ) ] \qquad ( 2 )$$

$$corrected SOH = current FCC / default FCC \qquad ( 3 )$$

When the OCV of the storage battery is within the uppermost change region CR1 or the lowermost change region CR4, the SOC estimated based on the SOC-OCV characteristics is relatively less affected by the state error of the storage battery 12. Therefore, the first reset SOC and the second reset SOC can be used to accurately correct the SOH. The correction reference time SOC (REF) in this case is an example of the SOC at the first reference time in the claims, and the control unit 60 also functions as the first reference SOC setting unit in the claims.

The FCC correction unit 63 corrects the FCC in Equation (1) used in the above-mentioned estimation process of the integrated SOC (t) to the current FCC calculated by Equation (2). This allows the estimation process of the integrated SOC (t) to be performed while suppressing the effects of fluctuations due to the degradation of the storage battery 12.

On the other hand, the fact that it is determined that the correction reference time SOC (REF) is not the second reset SOC (S240: NO) means that the estimation process of the integrated SOC (t) has been continued by repeatedly charging and discharging the storage battery 12 without the OCV of the storage battery 12 reaching the lowermost change region CR4. In other words, the change amount Q1(t) of the capacity of the storage battery 12 from the time when the previous SOH correction process was executed to the present time is relatively small. Therefore, the control unit 60 proceeds to S260 without executing the SOH correction process (S250).

If the temperature of the storage battery 12 is determined to be outside the predetermined temperature range (S230: NO), it is difficult to correct the SOH appropriately. Therefore, the control unit 60 proceeds to S290 without executing the SOH correction process (S250). If the temperature of the storage battery 12 is outside the predetermined temperature range, the correction reference time SOC (REF) is not updated. However, as described below, integrated reference time SOC(0) is updated.

In S260, the SOC update unit 71 (FIG. 1) of the control unit 60 performs the correction reference time SOC updating process. The correction reference time SOC updating process is a process to update the correction reference time SOC (REF) described above to the reset SOC (the first reset SOC and the second reset SOC). When the current OCV is within the uppermost change region CR1, the correction reference time SOC (REF) is updated to the first reset SOC (Sr1). In addition, the change amount Q1(t) and the change amount Q2(t) of the capacity of the storage battery 12 calculated by the coulomb counting processing unit 64 in Equations (2) and (5) used in this FCC estimation process are reset to zero.

Next, the control unit 60 determines whether the current SOH (corrected SOH) is less than or equal to a predetermined value (S270). The predetermined value is, e.g., a threshold value for determining whether the storage battery 12 can be normally recharged and discharged, and the fact that the SOH is greater than the predetermined value means that the storage battery 12 can be normally recharged and discharged, and the fact that the SOH is equal to or smaller than the predetermined value means, e.g., that the storage battery 12 has deteriorated and cannot be normally recharged and discharged. When it is determined that the SOH is equal to or smaller than the predetermined value (S270: YES), the control unit 60 executes a notification process (S280). Specifically, the control unit 60 notifies the outside world of an abnormality such as deterioration of the storage battery 12 via the interface unit 76. On the other hand, if the SOH is determined to be greater than the predetermined value (S270: NO), the control unit 60 proceeds to S290 without executing the notification process (S280).

In S290, the SOC update unit 71 updates the current integrated SOC (t), which is estimated in the above-mentioned estimation process of the integrated SOC (t), and the integrated reference time SOC (0) to the reset SOC. When the current OCV is within the uppermost change region CR1, the current integrated SOC(t) and the integrated reference time SOC(0) are updated to the first reset SOC (Sr1). In addition, the change amount Q(t) of the capacity of the storage battery 12 from the reference time calculated by the coulomb counting processing unit 64 in Equation (1) used in the estimation process of the integrated SOC(t) is reset to zero. This completes the SOC reset process.

A-2-3-2. When Current OCV is within the Lowermost Change Region CR4:

When it is determined that the current OCV is within the lowermost change region CR4 (S210: CR4), the reset SOC estimation unit 68 estimates the second reset SOC based on the current OCV of the storage battery 12, the SOC-OCV characteristics, and the SOH (S300). The SOC when the current OCV is within the other change regions CR (CR2 to CR4) other than the uppermost change region CR1 can be calculated, e.g., by the following Equation (4).

$$SOC = SOCint / SOH \qquad ( 4 )$$

SOCint is the SOC corresponding to the current OCV in the SOC-OCV table T1.

By dividing SOCint estimated by the OCV method by SOH, the SOC can be estimated even when the current OCV is within the other change regions CR (CR2 to CR4) other than the uppermost change region CR1 while suppressing the effect of the state error of the storage battery 12. In this case, the reset SOC estimation unit 68 functions as the second SOC estimation unit in the claims. In the example in FIG. 2, when the current OCV is within the lowermost change region CR4 in the SOC-OCV characteristics, the reset SOC estimation unit 68 refers to the SOC-OCV table T1 to estimate the SOC obtained by dividing the SOCint corresponding to the current OCV by the SOH (“Sr2” in FIG. 2) as the second reset SOC.

When it is determined that the temperature of the storage battery 12 is within the predetermined temperature range (S310: YES), the SOH correction unit 70 corrects the SOH on the condition that the OCV of the storage battery 12 has moved from the uppermost change region CR1 to the lowermost change region CR4.

Specifically, the control unit 60 determines whether the correction reference time SOC (REF) set in the previous SOH correction process is the first reset SOC (Sr1) estimated by the reset SOC estimation unit 68 when the OCV was within the uppermost change region CR1 (S320). The fact that it is determined that the correction reference time SOC (REF) is the first reset SOC (S320: YES) means that the OCV of the storage battery 12 has moved from the uppermost change region CR1 to the lowermost change region CR4.

Therefore, the SOH correction unit 70 executes the SOH correction process (S250). Specifically, the SOH correction unit 70 corrects the SOH based on the value Sr2 of the second reset SOC, the value Sr1 of the correction reference time SOC (REF) (first reset SOC), and the change amount Q2(t) of the storage battery 12 calculated by the coulomb counting processing unit 64 during the period in which the OCV of the storage battery 12 moved from the uppermost change region CR1 to the lowermost change region CR4 (S250, see arrow P2 in FIG. 2). For example, the corrected SOH can be calculated by the following Equations (3) and (5).

$$current FCC = Q 2 ( t ) / [ ( S r 2 ) - ( S r 1 ) ] \qquad ( 5 )$$

$$corrected SOH = current FCC / default FCC \qquad ( 3 )$$

The FCC correction unit 63 corrects the FCC in formula (1) used in the above-mentioned estimation process of the integrated SOC(t) to the current FCC calculated by Equation (3). This allows the estimation process of the integrated SOC(t) to be performed while suppressing the effects of fluctuations due to the degradation of the storage battery 12.

On the other hand, when it is determined that the correction reference time SOC (REF) is not the first reset SOC (S320: NO), the control unit 60 proceeds to S260 without executing the SOH correction process (S250). If the temperature of the storage battery 12 is determined to be outside the predetermined temperature range (S310: NO), the control unit 60 proceeds to S290 without executing the correction process (S250) for SOH. If the temperature of the storage battery 12 is outside the predetermined temperature range, the correction reference time SOC is not updated and the integrated reference time SOC (0) is updated.

In S260, when the current OCV is within the lowermost change region CR4, the correction reference time SOC (REF) is updated to the second reset SOC (Sr2). In addition, the change amount Q1(t) and the change amount Q2(t) of the capacity of the storage battery 12 calculated by the coulomb counting processing unit 64 in Equations (2) and (5) used in this FCC estimation process are reset to zero. Furthermore, in S290, the current integrated SOC(t) and the integrated reference time SOC (0) are updated to the second reset SOC (Sr2). In addition, the change amount Q(t) of the capacity of the storage battery 12 from the reference time calculated by the coulomb counting processing unit 64 in Equation (1) used in the estimation process of the integrated SOC(t) is reset to zero.

A-2-3-3. When Current OCV is within Intermediate Change Region CR2, CR3:

When it is determined that the current OCV is within the intermediate change region CR2 or CR3 (S210: CR2, CR3), the reset SOC estimation unit 68 estimates the third reset SOC (“Sr3” in FIG. 2) based on the current OCV of the storage battery 12, the SOC-OCV characteristics, and the SOH (S400). Specifically, the third reset SOC can be calculated by the above Equation (4) used when the current OCV is within the lowermost change region CR4, as in the process of S300 above. The control unit 60 then proceeds to S290. In S290, the current integrated SOC (t) and the integrated reference time SOC (0) are updated to the third reset SOC. As described above, when the OCV of the storage battery 12 is within the intermediate change region CR2 or CR3, the effect of the state error of the storage battery 12 on the SOC estimated based on the SOC-OCV characteristics is relatively large. Therefore, when the OCV of the storage battery 12 is within the intermediate change region CR2 or CR3, the SOH is not corrected and the correction reference time SOC (REF) is not updated.

### A-3. Effects of Embodiment:

As explained above, when the OCV of the storage battery 12 is within the uppermost change region CR1 including 100% SOC, the effect of the storage battery state error (e.g., individual differences in the storage batteries 12 at the time of shipment and aging of the storage battery 12) on the SOC estimated based on the SOC-OCV characteristics is small, and when the OCV of the storage battery 12 is within the other change regions CR2 to CR4, the effect of the storage battery state error on the SOC estimated based on the SOC-OCV characteristics is large (see FIG. 2).

Therefore, in the storage battery management device 20 of this embodiment, when the OCV of the storage battery 12 is within the uppermost change region CR1 (S210: CR1 in FIG. 6), the first SOC (first reset SOC) is estimated based on the OCV of the storage battery 12 and the SOC-OCV characteristics (S220). On the other hand, when the OCV of the storage battery 12 is within the other change regions CR2 to CR4 (S210: CR2 to CR4), the second SOC (second reset SOC, third reset SOC) is estimated based on the OCV of the storage battery 12, the SOC-OCV characteristics, and the SOH that correlates with the degradation state of the storage battery 12 (S300, S400). As a result, this embodiment can accurately estimate the SOC of the storage battery 12 while suppressing the decrease in the estimation accuracy of the SOC caused by the state error of the storage battery 12.

### B. Modifications

The technology disclosed herein is not limited to the embodiments described above but can be modified into various forms without departing from the spirit of the present invention; for example, the following modifications are possible.

The configuration of the battery device 100 in the above embodiments is only an example and can be modified in various ways. For example, in each of the above embodiments, the number of the storage batteries 12 constituting the battery assembly 10 can be modified as desired. In the above embodiments, one thermometer 26 may be provided for each of the storage batteries 12. The thermometer 26 may be omitted.

In the above embodiment, the storage battery is exemplified by an iron phosphate lithium-ion battery, but any other secondary or primary battery may be used as long as the storage battery has SOC-OCV characteristics that include a first region where the OCV change rate is a predetermined value or less, and a change region where the OCV change rate exceeds the predetermined value. The predetermined value is not limited to 2 mV/% but can be freely selected. The number of change regions CR and plateau regions PR can be freely changed. In the above embodiment, the second change region is exemplified by the lowermost change region CR4, but the second change region can be any change region where the OCV is below a predetermined value, e.g., in FIG. 2, in addition to the lowermost change region CR4, it may include the intermediate change region CR3 or part of the intermediate change region CR3.

In the above embodiment, the contents of the SOC-OCV table T1 and the region classification-OCV table T2 are only examples and can be modified in various ways. It is not necessary that at least one of the SOC-OCV table T1 or region classification-OCV table T2 is recorded in the recording unit 72. Also, in each of the above embodiments, at least one of each functional part of the control unit 60 may be omitted.

The content of the SOC estimation process in the above embodiments is only an example and can be modified in various ways. For example, in the above embodiment, the SOC estimation process is to estimate SOC individually for each of the storage batteries 12 constituting the battery assembly 10, but the SOC may be estimated for the entire battery assembly 10. In the OCV acquisition process in the above embodiment, the method of acquiring the battery voltage of the storage batteries 12 in a stable state as the OCV was adopted (S110 to S130 in FIG. 6), but a known method may be adopted, such as a method of estimating the OCV based on changes in the internal resistance and the battery voltage of the storage batteries 12.

In the estimation process of the integrated SOC(t) in the above embodiment, the FCC may be set as a fixed value, and the integrated SOC(t) may be estimated based on the SOC(0) at the reference time and the change amount Q(t) of the capacity of the storage battery 12 from the reference time calculated by the coulomb counting processing unit 64. In the SOC estimation process in the above embodiment, the reference SOC update process (S260) may not be executed. Even in such a configuration, the SOC of the storage battery 12 can be accurately estimated by correcting the integrated SOC(t).

In the above embodiment, the correlation value is exemplified by the SOH, but it is not limited to this, and other values (parameters) that correlate with the degradation state of the storage battery 12 (the battery assembly 10) may also be used.

In the above embodiment, the condition for executing the SOH correction process (S250) is that the storage battery 12 is within a predetermined temperature range, but other conditions (e.g., environmental conditions such as humidity or electrical conditions (overcurrent, overvoltage, and the like) of the storage battery 12) may be used.

### REFERENCE SIGNS LIST

10: battery assembly, 12: storage battery, 20: storage battery management device, 22: voltmeter, 24: ammeter, 26: thermometer, 28: monitoring unit, 40: line switch, 42: positive terminal, 44: negative terminal, 60: control unit, 62: OCV acquisition unit, 63: FCC correction unit, 64: coulomb counting processing unit, 66: integrated SOC estimation unit, 68: reset SOC estimation unit, 70: SOH correction unit, 71: SOC update unit, 72: recording unit, 74: history unit, 76: interface unit, 100: battery device, CR: change region, PR: plateau region

1. A storage battery management device for managing a storage battery having SOC-OCV characteristics including a plateau region in which an OCV change rate, which is the absolute value of the change amount of the OCV relative to the change amount of the SOC, is relatively low, and multiple change regions in which the OCV change rate is relatively high, the storage battery management device comprising:
an OCV acquisition unit that acquires the OCV of the storage battery;
a first SOC estimation unit that estimates a first SOC based on the OCV of the storage battery and the SOC-OCV characteristics when the OCV of the storage battery acquired by the OCV acquisition unit is within a first change region which is the change region including 100% SOC; and
a second SOC estimation unit that estimates a second SOC based on the OCV of the storage battery, the SOC-OCV characteristics, and a correlation value that correlates with the degradation state of the storage battery when the OCV of the storage battery is within the other change regions other than the first change region.

2. The storage battery management device according to claim 1, further comprising:
a current measurement unit that measures the current flowing through the storage battery;
a coulomb counting processing unit that calculates the capacity of the storage battery by integrating the current measured by the current measurement unit;
a first reference SOC setting unit that sets the SOC estimated by the first SOC estimation unit as the SOC at the first reference time when the OCV of the storage battery is within the first change region; and
a correlation value correction unit that corrects the correlation value on the condition that the OCV of the storage battery moves from the first change region to a second change region where the OCV is equal to or smaller than a predetermined value among the other change regions, wherein
the correlation value correction unit corrects the correlation value based on the SOC estimated by the second SOC estimation unit based on the OCV after moving to the second change region, the SOC at the first reference time, and the change amount of the capacity of the storage battery calculated by the coulomb counting processing unit during the time period in which the OCV of the storage battery moves from the first change region to the second change region.

3. The storage battery management device according to claim 1, further comprising:
a current measurement unit that measures the current flowing through the storage battery;
a coulomb counting processing unit that calculates the capacity of the storage battery by integrating the current measured by the current measurement unit;
a first reference SOC setting unit that sets the SOC estimated by the second SOC estimation unit as the SOC at the first reference time when the OCV of the storage battery is within a second change region where the OCV is equal to or smaller than a predetermined value among the other change regions; and
a correlation value correction unit that corrects the correlation value on the condition that the OCV of the storage battery moves from the second change region to the first change region, wherein
the correlation value correction unit corrects the correlation value based on the SOC estimated by the first SOC estimation unit based on the OCV after moving to the first change region, the SOC at the first reference time, and the change amount of the capacity of the storage battery calculated by the coulomb counting processing unit during the time period in which the OCV of the storage battery moves from the second change region to the first change region.

4. The storage battery management device according to claim 2, further comprising:
a second reference SOC setting unit that sets the SOC estimated by the first SOC estimation unit or the second SOC estimation unit as the SOC at the second reference time;
an integrated SOC estimation unit that estimates the integrated SOC of the storage battery based on the SOC at the second reference time, the change amount of the capacity of the storage battery from the second reference time calculated by the coulomb counting processing unit, and the FCC of the storage battery; and
an FCC correction unit that corrects the FCC based on the corrected correlation value corrected by the correlation value correction unit.

5. A method for managing a storage battery having SOC-OCV characteristics including a plateau region in which an OCV change rate, which is the absolute value of the change amount of the OCV relative to the change amount of the SOC, is relatively low, and multiple change regions in which the OCV change rate is relatively high, the method comprising:
a step of acquiring the OCV of the storage battery; and
a step of estimating the first SOC based on the OCV of the storage battery and the SOC-OCV characteristics when the acquired OCV of the storage battery is within a first change region which is the change region including 100% SOC; and
a step of estimating a second SOC based on the OCV of the storage battery, the SOC-OCV characteristics, and a correlation value that correlates with the degradation state of the storage battery when the OCV of the storage battery is within the other change regions other than the first change region.

6. The storage battery management device according to claim 3, further comprising:
a second reference SOC setting unit that sets the SOC estimated by the first SOC estimation unit or the second SOC estimation unit as the SOC at the second reference time;
an integrated SOC estimation unit that estimates the integrated SOC of the storage battery based on the SOC at the second reference time, the change amount of the capacity of the storage battery from the second reference time calculated by the coulomb counting processing unit, and the FCC of the storage battery; and
an FCC correction unit that corrects the FCC based on the corrected correlation value corrected by the correlation value correction unit.
